(19) United States
(12) Patent Application Publication
(10) Pub. No.: US 2025/0299713 A1
(43) Pub. Date: Sep. 25, 2025

(54) HYBRID TIMING MODE FOR PIPELINED CACHE MEMORIES

(71) Applicant: NVIDIA CORPORATION, Santa Clara, CA (US)

(72) Inventors: Balachander GANESAN, Bengaluru (IN); Mallikarjun Chandrashekar MATHRUBHAI, Bengaluru (IN); Suhail Mannan JADLIWALA, Bengaluru (IN); Karthik BALAKRISHNAN, Bengaluru (IN); Harsha Sringeshwar BHARADHWAJ, Bengaluru (IN)

(21) Appl. No.: 18/757,206

(22) Filed: Jun. 27, 2024

(30) Foreign Application Priority Data
Mar. 23, 2024 (IN) 202441022713

(51) Int. Cl. G11C 7/22; G11C 7/08; G11C 8/08

(52) U.S. Cl. CPC G11C 7/222; G11C 7/08; G11C 8/08

(57) ABSTRACT

In various embodiments, a computer-implemented method for controlling cache memory accesses comprises transmitting a first clock signal to the cache memory, where a first rising edge of the first clock signal asserts a word line, and transmitting a second clock signal to the cache memory, where a first rising edge of the second clock signal precedes a second rising edge of the first clock signal, and the first rising edge of the second clock signal de-asserts the word line.

### CROSS-REFERENCE TO RELATED APPLICATIONS

This application claims priority benefit of the Indian Provisional Patent Application titled, “HYBRID TIMING MODE FOR PIPELINED CACHE MEMORIES,” filed on Mar. 23, 2024, and having Application No. 202441022713. The subject matter of this related application is hereby incorporated herein by reference.

### BACKGROUND

### Field of the Various Embodiments

The various embodiments relate generally to computer systems and electronics and, more specifically, to a hybrid timing mode for pipelined cache memories.

### Description of the Related Art

Many modern computing systems use instruction pipelining to implement instruction-level parallelism for one or more processors. In an instruction pipeline, data is retrieved from bit cells once per clock cycle. For example, a cache memory has an architecture that is configured to periodically retrieve data from one or more bit cells. The cache memory first receives the rising edge of a clock signal to enable a word line corresponding to a single address for read access or write access. The cache memory then receives the next rising edge of the clock signal to close access to the word line. During this access period, bit cells attached to the word line are enabled and are available for either the read access or the write access. Separate pairs of bit lines are attached to the respective bit cells, with separate sensing cells attached to each pair of bit lines. At the end of a clock cycle during a read operation, each sensing cell compares a differential between the pair of bit lines to a threshold to determine the data value stored in the bit line. At the end of a clock cycle during a write operation, incoming data is driven onto the respective pairs of bit lines in order to store the data in the respective bit cells.

Many modern computing systems also include large cache memories. Large cache memories typically densely group together numerous bit cells into arrays of bit rows and bit columns. Arranging the bit cells in this manner decreases the physical area the cache memory occupies, thereby increasing the amount of data that the cache memory is able to store. One consequence of densely arranging bit cells in this manner is that the bit array includes long bit columns, where many bit cells are attached to a single pair of bit lines. Accordingly, the large cache memories include large numbers of addresses that include separate bit cells that are connected along common bit lines. Because various addresses have to be accessed during many cycles to enable read access or write access, a common bit line that is connected to the separate bit cells for the various addresses is continually charged.

One drawback with conventional large cache memories is that such systems continually expend excess power due to the timing of the read and write cycles. For example, during a given read cycle, the word line for a given address is continually enabled for the entire clock period to enable a read from each of the bit cells included in the address. The sensing circuits monitoring differentials between pairs of bit lines for the respective bit cells of the enabled address compare differentials between the pairs of bit lines at the end of the clock period. However, the pairs of bit lines do not require the entire clock period to reach the differential required for discharging. As a result, the pairs of bit lines discharge more than is necessary during the clock cycle. The pairs of bit lines continually discharge, even after the differential is initially obtained, discharging any time during the clock period where the differential is above a predetermined threshold. The pairs of bit lines typically discharge more than is necessary during a single clock period, which needlessly consumes power. Similarly, during a write cycle, the word line for a given address is continually enabled for the entire clock period to enable a write to each of the bit cells included in the address. During the clock period, the bit cells that are half-selected (e.g., bit cells connected the bit line pair not chosen by a column decoder), discharge the bit lines, thereby wasting dynamic power by keeping the word line on for longer than is necessary to complete the write cycle. Conventional systems attempt to reduce the amount of power wasted by the memory by reducing the clock period to shorten the time that the word line is enabled. However, reducing the clock period negatively affects the other components of the modern computing system that also operate along the instruction pipeline. For example, the processor included in the modern computing system may not successfully fetch or decode instructions within the reduced clock period, negatively affecting the performance of the modern computing system as a whole.

As the foregoing illustrates, what is needed in the art are techniques to reduce the power consumption when reading data from and writing data to cache memories.

### SUMMARY

In various embodiments, a computer-implemented method for controlling cache memory accesses comprises transmitting a first clock signal to the cache memory, where a first rising edge of the first clock signal asserts a word line, and transmitting a second clock signal to the cache memory, where a first rising edge of the second clock signal precedes a second rising edge of the first clock signal, and the first rising edge of the second clock signal de-asserts the word line.

At least one technical advantage of the disclosed technique relative to the prior art is that the disclosed techniques reduce the amount of power consumed when data is read from or written to cache memory. More specifically, with the disclosed techniques, a memory controller includes logic to provide both a clock signal and a self-timing clock signal to a cache memory. When the cache memory is operable to operate in a self-time mode, the rising edge of the self-timing clock signal precedes the second rising edge of the clock signal, which allows the word line to be disabled earlier and the sense amplifier earlier to be enabled, thereby reducing the overall amount of dynamic power consumed by the cache memory due to the word line being enabled. Further, by triggering the word line to be disabled without modifying the clock signal, the memory controller can reduce the power consumption of the cache memory without modifying the timing of data transmission into or out of the cache memory. The cache memory can thus be included in various instruction pipelines without negatively impacting the operations of other components within the instruction pipeline running on that same clock signal. These technical advantages provide one or more technological improvements over prior art approaches.

### BRIEF DESCRIPTION OF THE DRAWINGS

So that the manner in which the above recited features of the various embodiments can be understood in detail, a more particular description of the inventive concepts, briefly summarized above, may be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.

FIG. 1 is a block diagram of a computer system configured to implement one or more aspects of the various embodiments;

FIG. 2 is a block diagram of a parallel processing unit (PPU) included in the parallel processing subsystem of FIG. 1, according to the various embodiments;

FIG. 3 is a block diagram of a general processing cluster (GPC) included in the parallel processing unit of FIG. 2, according to the various embodiments;

FIG. 4 is a more detailed illustration of an exemplar processing cluster array included in the parallel processing unit of FIG. 2, according to the various embodiments;

FIG. 5 is a block diagram of a memory array and access logic of a cache memory of FIG. 4, according to the various embodiments;

FIG. 6 illustrates exemplar waveforms associated with the memory array and access logic of FIG. 4 operating in a sync timing mode, according to the various embodiments;

FIG. 7 illustrates exemplar waveforms associated with the memory array and access logic of FIG. 4 operating in a self-timing trigger mode, according to the various embodiments;

FIG. 8 illustrates exemplar waveforms associated with the memory array and access logic of FIG. 4 operating in a sync timing trigger mode, according the various embodiments;

FIGS. 9A-9B is a diagram of sequential logic included in the memory controller of FIG. 4, according to the various embodiments; and

FIG. 10 sets forth a flowchart of method steps for reading data from and writing data to a cache memory, according to the various embodiments.

### DETAILED DESCRIPTION

In the following description, numerous specific details are set forth to provide a more thorough understanding of the various embodiments. However, it will be apparent to one skilled in the art that the inventive concepts may be practiced without one or more of these specific details. For explanatory purposes, multiple instances of like objects are symbolized with reference numbers identifying the object and parenthetical numbers(s) identifying the instance where needed.

### System Overview

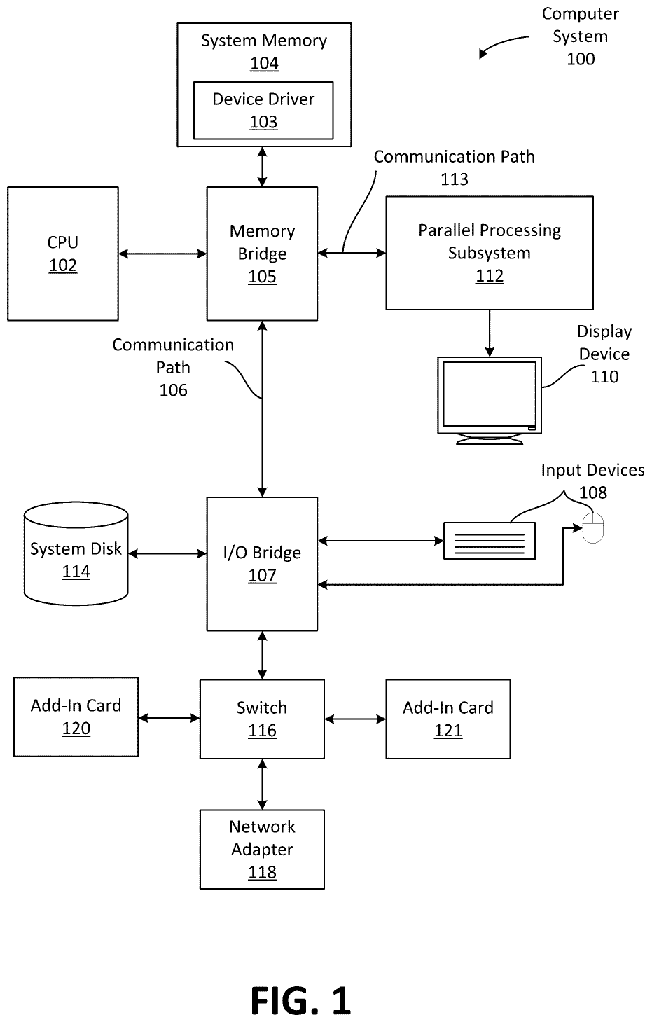

FIG. 1 is a block diagram of a computing system 100 configured to implement one or more aspects of the various embodiments. As shown, computing system 100 includes, without limitation, a central processing unit (CPU) 102 and a system memory 104 coupled to a parallel processing subsystem 112 via a memory bridge 105 and/or a communication path 113. Memory bridge 105 is further coupled to an I/O (input/output) bridge 107 via a communication path 106, and/or I/O bridge 107 is, in turn, coupled to a switch 116.

In operation, I/O bridge 107 is configured to receive user input information from input devices 108, such as a keyboard or a mouse, and/or forward the input information to CPU 102 for processing via communication path 106 and/or memory bridge 105. In some examples, without limitation, input devices 108 are employed to verify the identities of one or more users in order to permit access of computing system 100 to authorized users and/or deny access of computing system 100 to unauthorized users. Switch 116 is configured to provide connections between I/O bridge 107 and/or other components of the computing system 100, such as a network adapter 118 and/or various add-in cards 120 and 121. In some examples, without limitation, network adapter 118 serves as the primary or exclusive input device to receive input data for processing via the disclosed techniques.

As also shown, I/O bridge 107 is coupled to a system disk 114 that can be configured to store content and/or applications and/or data for use by CPU 102 and/or parallel processing subsystem 112. As a general matter, system disk 114 provides non-volatile storage for applications and/or data and can include fixed or removable hard disk drives, flash memory devices, and/or CD-ROM (compact disc read-only-memory), DVD-ROM (digital versatile disc-ROM), Blu-ray, HD-DVD (high definition DVD), or other magnetic, optical, or solid state storage devices. Finally, although not explicitly shown, other components, such as universal serial bus or other port connections, compact disc drives, digital versatile disc drives, film recording devices, and/or the like, can be connected to I/O bridge 107 as well.

In various embodiments, memory bridge 105 can be a Northbridge chip, and/or I/O bridge 107 can be a Southbridge chip. In addition, communication paths 106 and/or 113, as well as other communication paths within computing system 100, can be implemented using any technically suitable protocols, including, without limitation, Peripheral Component Interconnect Express (PCIe), HyperTransport, or any other bus or point-to-point communication protocol known in the art.

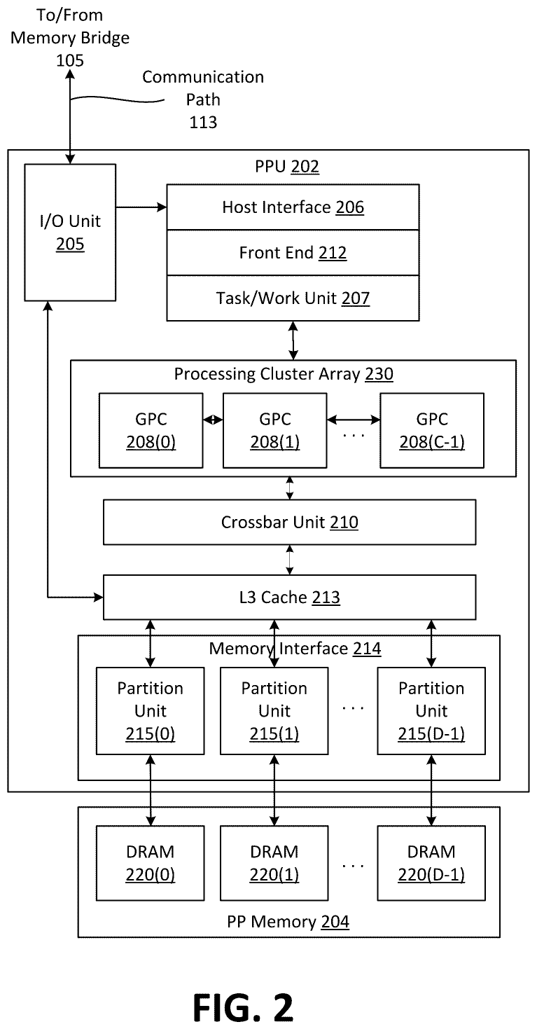

In some embodiments, parallel processing subsystem 112 comprises a graphics subsystem that delivers pixels to a display device 110 that can be any conventional cathode ray tube, liquid crystal display, light-emitting diode display, or the like. In such embodiments, the parallel processing subsystem 112 incorporates circuitry optimized for graphics and/or video processing, including, for example, without limitation, video output circuitry. As described in greater detail herein in FIG. 2, such circuitry can be incorporated across one or more parallels included within parallel processing subsystem 112. Parallel processing subsystem 112 includes one or more processing units that can execute instructions such as a central processing unit (CPU), a parallel processing unit (PPU) of FIGS. 2-4, a graphics processing unit (GPU), a direct memory access (DMA) unit, an intelligence processing unit (IPU), neural processing unit (NAU), tensor processing unit (TPU), neural network processor (NNP), a data processing unit (DPU), a vision processing unit (VPU), an application specific integrated circuit (ASIC), a field-programmable gate array (FPGA), and/or the like.

In some embodiments, parallel processing subsystem 112 includes two processors, referred to herein as a primary processor (normally a CPU) and/or a secondary processor. Typically, the primary processor is a CPU and/or the secondary processor is a GPU. Additionally or alternatively, each of the primary processor and/or the secondary processor can be any one or more of the types of parallels disclosed herein, in any technically feasible combination. The secondary processor receives secure commands from the primary processor via a communication path that is not secured. The secondary processor accesses a memory and/or other storage system, such as system memory 104, Compute eXpress Link (CXL) memory expanders, memory managed disk storage, on-chip memory, and/or the like. The secondary processor accesses this memory and/or other storage system across an insecure connection. The primary processor and/or the secondary processor can communicate with one another via a GPU-to-GPU communications channel, such as Nvidia Link (NVLink). Further, the primary processor and/or the secondary processor can communicate with one another via network adapter 118. In general, the distinction between an insecure communication path and/or a secure communication path is application dependent. A particular application program generally considers communications within a die or package to be secure. Communications of unencrypted data over a standard communications channel, such as PCIe, are considered to be unsecure.

In some embodiments, the parallel processing subsystem 112 incorporates circuitry optimized for general purpose and/or compute processing. Again, such circuitry can be incorporated across one or more parallel processing units included within parallel processing subsystem 112 that are configured to perform such general purpose and/or compute operations. In yet other embodiments, the one or more parallel processing units included within parallel processing subsystem 112 can be configured to perform graphics processing, general purpose processing, and/or compute processing operations. System memory 104 includes at least one device driver 103 configured to manage the processing operations of the one or more parallels within parallel processing subsystem 112.

In various embodiments, parallel processing subsystem 112 can be integrated with one or more of the other elements of FIG. 1 to form a single system. For example, without limitation, parallel processing subsystem 112 can be integrated with CPU 102 and/or other connection circuitry on a single chip to form a system on chip (SoC).

It will be appreciated that the system shown herein is illustrative and that variations and/or modifications are possible. The connection topology, including the number and/or arrangement of bridges, the number of CPUs 102, and/or the number of parallel processing subsystems 112, can be modified as desired. For example, without limitation, in some embodiments, system memory 104 can be connected to CPU 102 directly rather than through memory bridge 105, and/or other devices would communicate with system memory 104 via memory bridge 105 and/or CPU 102. In other alternative topologies, parallel processing subsystem 112 can be connected to I/O bridge 107 or directly to CPU 102, rather than to memory bridge 105. In still other embodiments, I/O bridge 107 and/or memory bridge 105 can be integrated into a single chip instead of existing as one or more discrete devices. Lastly, in certain embodiments, one or more components shown in FIG. 1 can not be present. For example, without limitation, switch 116 can be eliminated, and/or network adapter 118 and/or add-in cards 120, 121 would connect directly to I/O bridge 107.

FIG. 2 is a block diagram of a parallel processing unit (PPU) 202 included in the parallel processing subsystem 112 of FIG. 1, according to various embodiments. Although FIG. 2 depicts one PPU 202, as indicated herein, parallel processing subsystem 112 can include any number of PPUs 202. Further, the PPU 202 of FIG. 2 is one non-limiting example of a parallel included in parallel processing subsystem 112 of FIG. 1. Alternative parallels include, without limitation, CPUs, GPUs, DMA units, IPUs, NPUs, TPUs, NNPs, DPUs, VPUs, ASICs, FPGAs, and/or the like. The techniques disclosed in FIGS. 2-4 with respect to PPU 202 apply equally to any type of parallel(s) included within parallel processing subsystem 112, in any combination. As shown, PPU 202 is coupled to a local parallel processing (PP) memory 204. PPU 202 and/or PP memory 204 can be implemented using one or more integrated circuit devices, such as programmable processors, application specific integrated circuits (ASICs), or memory devices, or in any other technically feasible fashion.

In some embodiments, PPU 202 comprises a graphics processing unit (GPU) that can be configured to implement a graphics rendering pipeline to perform various operations related to generating pixel data based on graphics data supplied by CPU 102 and/or system memory 104. When processing graphics data, PP memory 204 can be used as graphics memory that stores one or more conventional frame buffers and, if needed, one or more other render targets as well. Among other things, PP memory 204 can be used to store and/or update pixel data and/or deliver final pixel data or display frames to display device 110 for display. In some embodiments, PPU 202 also can be configured for general-purpose processing and/or compute operations.

In operation, CPU 102 is the master processor of computing system 100, controlling and/or coordinating operations of other system components. In particular, CPU 102 issues commands that control the operation of PPU 202. In some embodiments, CPU 102 writes a stream of commands for PPU 202 to a data structure (not explicitly shown in either FIG. 1 or FIG. 2) that can be located in system memory 104, PP memory 204, or another storage location accessible to both CPU 102 and/or PPU 202. Additionally or alternatively, processors and/or processing units other than CPU 102 can write one or more streams of commands for PPU 202 to a data structure. A pointer to the data structure is written to a pushbuffer to initiate processing of the stream of commands in the data structure. The PPU 202 reads command streams from the pushbuffer and/or then executes commands asynchronously relative to the operation of CPU 102. In embodiments where multiple pushbuffers are generated, execution priorities can be specified for each pushbuffer by an application program via device driver 103 to control scheduling of the different pushbuffers.

As also shown, PPU 202 includes an I/O (input/output) unit 205 that communicates with the rest of computing system 100 via the communication path 113 and/or memory bridge 105. I/O unit 205 generates packets (or other signals) for transmission on communication path 113 and/or also receives all incoming packets (or other signals) from communication path 113, directing the incoming packets to appropriate components of PPU 202. For example, without limitation, commands related to processing tasks can be directed to a host interface 206, while commands related to memory operations (e.g., reading from or writing to PP memory 204) can be directed to a crossbar unit 210. Host interface 206 reads each pushbuffer and/or transmits the command stream stored in the pushbuffer to a front end 212.

As mentioned herein in conjunction with FIG. 1, the connection of PPU 202 to the rest of computing system 100 can be varied. In some embodiments, parallel processing subsystem 112, which includes at least one PPU 202, is implemented as an add-in card that can be inserted into an expansion slot of computing system 100. In other embodiments, PPU 202 can be integrated on a single chip with a bus bridge, such as memory bridge 105 or I/O bridge 107. Again, in still other embodiments, some or all of the elements of PPU 202 can be included along with CPU 102 in a single integrated circuit or system of chip (SoC).

In operation, front end 212 transmits processing tasks received from host interface 206 to a work distribution unit (not shown) within task/work unit 207. The work distribution unit receives pointers to processing tasks that are encoded as task metadata (TMD) and/or stored in memory. The pointers to TMDs are included in a command stream that is stored as a pushbuffer and received by the front end 212 from the host interface 206. Processing tasks that can be encoded as TMDs include indices associated with the data to be processed as well as state parameters and/or commands that define how the data is to be processed. For example, without limitation, the state parameters and/or commands can define the program to be executed on the data. The task/work unit 207 receives tasks from the front end 212 and/or ensures that GPCs 208 are configured to a valid state before the processing task specified by each one of the TMDs is initiated. A priority can be specified for each TMD that is used to schedule the execution of the processing task. Processing tasks also can be received from the processing cluster array 230. Optionally, the TMD can include a parameter that controls whether the TMD is added to the head or the tail of a list of processing tasks (or to a list of pointers to the processing tasks), thereby providing another level of control over execution priority.

PPU 202 advantageously implements a highly parallel processing architecture based on a processing cluster array 230 that includes a set of C general processing clusters (GPCs) 208, where C≥1. Each GPC 208 is capable of executing a large number (e.g., hundreds or thousands) of threads concurrently, where each thread is an instance of a program. In various applications, different GPCs 208 can be allocated for processing different types of programs or for performing different types of computations. The allocation of GPCs 208 can vary depending on the workload arising for each type of program or computation. As will be described in more detail herein, one or more GPCs 208 can concurrently execute threads in a cooperative thread array (CTA) that cooperate and share data to perform collective computations.

In the illustrated example of FIG. 2, PPU 202 further includes a level three (L3) cache memory, or L3 cache 213. As will be described in more detail herein, in various embodiments, the L3 cache 213 is shared by GPCs 208 included in the PPU 202. In a cache hierarchy, the L3 cache 213 is positioned further upstream from streaming multiprocessors (SMs) executing threads than level one (L1) caches (not shown) and level two (L2) caches (not shown) included in the PPU 202. In some examples, such as in the illustrated example of FIG. 2, the L3 cache 213 is the highest-level cache (HLC) in a cache hierarchy. In some examples, the PPU 202 and/or the parallel processing subsystem 112 includes one or more additional levels of cache (e.g., level four (L4) cache, level five (L5) cache, etc.) that are positioned further upstream in a cache hierarchy. In some examples, the PPU does not include an L3 cache 213. In such examples, the L2 caches included in the PPU 202 are at the highest level of cache in the PPU 202 and/or the parallel processing subsystem 112.

The L3 cache 213 is coupled to a memory interface 214. The memory interface 214 includes a set of D of partition units 215, where D≥1. Each partition unit 215 is coupled to one or more dynamic random-access memories (DRAMs) 220 residing within PP memory 204. In one embodiment, the number of partition units 215 equals the number of DRAMs 220, and/or each partition unit 215 is coupled to a different DRAM 220. In other embodiments, the number of partition units 215 can be different than the number of DRAMs 220. In some embodiments, one or more caches, such as L3 cache 213, can also be partitioned. For example, every L3 cache partition could handle read and write accesses for a specific address range. Persons of ordinary skill in the art will appreciate that a DRAM 220 can be replaced with any other technically suitable storage device. In operation, various render targets, such as texture maps and/or frame buffers, can be stored across DRAMs 220, allowing partition units 215 to write portions of each render target in parallel to efficiently use the available bandwidth of PP memory 204.

A given GPC 208 can process data to be written to any of the DRAMs 220 within PP memory 204. Crossbar unit 210 is configured to route the output of each GPC 208 to the input of any partition unit 215 or to any other GPC 208 for further processing. GPCs 208 communicate with memory interface 214 via crossbar unit 210 to read from or write to various DRAMs 220. In one embodiment, crossbar unit 210 has a connection to I/O unit 205, in addition to a connection to PP memory 204 via memory interface 214, thereby enabling the processing cores within the different GPCs 208 to communicate with system memory 104 or other memory not local to PPU 202. In the embodiment of FIG. 2, crossbar unit 210 is directly connected with I/O unit 205. In various embodiments, crossbar unit 210 can use virtual channels to separate traffic streams between the GPCs 208 and/or partition units 215.

Again, GPCs 208 can be programmed to execute processing tasks relating to a wide variety of applications, including, without limitation, linear and/or nonlinear data transforms, filtering of video and/or audio data, modeling operations (e.g., applying laws of physics to determine position, velocity, and/or other attributes of objects), image rendering operations (e.g., tessellation shader, vertex shader, geometry shader, and/or pixel/fragment shader programs), general compute operations, etc. In operation, PPU 202 is configured to transfer data from system memory 104 and/or PP memory 204 to one or more on-chip memory units, process the data, and/or write result data back to system memory 104 and/or PP memory 204. The result data can then be accessed by other system components, including CPU 102, another PPU 202 within parallel processing subsystem 112, or another parallel processing subsystem 112 within computing system 100.

As noted herein, any number of PPUs 202 can be included in a parallel processing subsystem 112. For example, without limitation, multiple PPUs 202 can be provided on a single add-in card, or multiple add-in cards can be connected to communication path 113, or one or more of PPUs 202 can be integrated into a bridge chip. PPUs 202 in a multi-PPU system can be identical to or different from one another. For example, without limitation, different PPUs 202 might have different numbers of processing cores and/or different amounts of PP memory 204. In implementations where multiple PPUs 202 are present, those PPUs can be operated in parallel to process data at a higher throughput than is possible with a single PPU 202. Systems incorporating one or more PPUs 202 can be implemented in a variety of configurations and/or form factors, including, without limitation, desktops, laptops, handheld personal computers or other handheld devices, servers, workstations, game consoles, embedded systems, and/or the like.

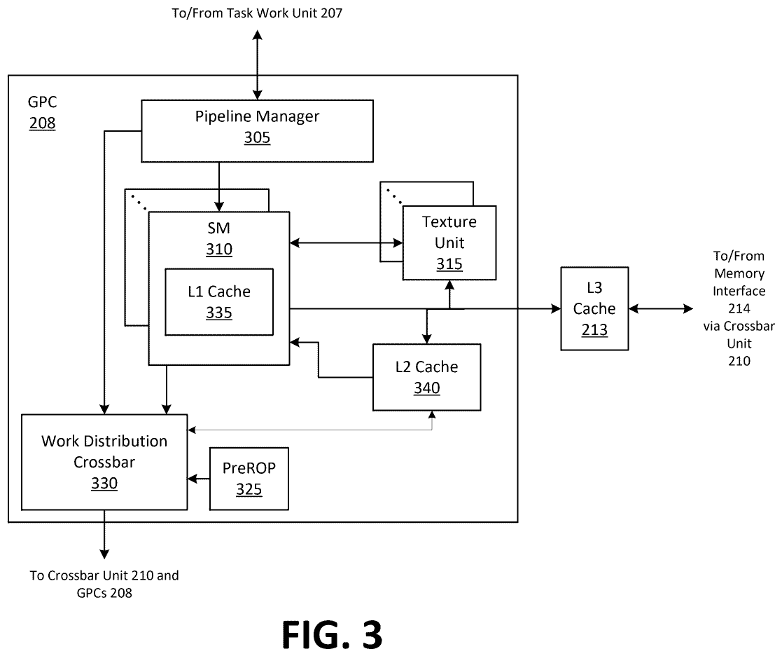

FIG. 3 is a block diagram of a general processing cluster (GPC) 208 included in the parallel processing unit (PPU) 202 of FIG. 2, according to various embodiments. In operation, GPC 208 can be configured to execute a large number of threads in parallel to perform graphics, general processing and/or compute operations. As used herein, a “thread” refers to an instance of a particular program executing on a particular set of input data. In some embodiments, single-instruction, multiple-data (SIMD) instruction issue techniques are used to support parallel execution of a large number of threads without providing multiple independent instruction units. In other embodiments, single-instruction, multiple-thread (SIMT) techniques are used to support parallel execution of a large number of generally synchronized threads, using a common instruction unit configured to issue instructions to a set of processing engines within GPC 208. Unlike a SIMD execution regime, where all processing engines typically execute identical instructions, SIMT execution allows different threads to more readily follow divergent execution paths through a given program. Persons of ordinary skill in the art will understand that a SIMD processing regime represents a functional subset of a SIMT processing regime.

Operation of GPC 208 is controlled via a pipeline manager 305 that distributes processing tasks received from a work distribution unit (not shown) within task/work unit 207 to one or more streaming multiprocessors (SMs) 310. Pipeline manager 305 can also be configured to control a work distribution crossbar 330 by specifying destinations for processed data output by SMs 310.

In one embodiment, GPC 208 includes a set of Q SMs 310, where Q≥1. Also, each SM 310 includes a set of functional execution units (not shown), such as execution units and/or load-store units. Processing operations specific to any of the functional execution units can be pipelined, which enables a new instruction to be issued for execution before a previous instruction has completed execution. Any combination of functional execution units within a given SM 310 can be provided. In various embodiments, the functional execution units can be configured to support a variety of different operations including integer and/or floating point arithmetic (e.g., addition and/or multiplication), comparison operations, Boolean operations (e.g., AND, OR, XOR), bit-shifting, and/or computation of various algebraic functions (e.g., planar interpolation and/or trigonometric, exponential, and/or logarithmic functions, etc.). Advantageously, the same functional execution unit can be configured to perform different operations.

In operation, each SM 310 is configured to process one or more thread groups. As used herein, a “thread group” or “warp” refers to a group of threads concurrently executing the same program on different input data, with one thread of the group being assigned to a different execution unit within an SM 310. A thread group can include fewer threads than the number of execution units within the SM 310, in which case some of the execution can be idle during cycles when that thread group is being processed. A thread group can also include more threads than the number of execution units within the SM 310, in which case processing can occur over consecutive clock cycles and/or across multiple SMs 310. Since each SM 310 can support up to G thread groups concurrently, it follows that up to G*Q thread groups can be executing in GPC 208 at any given time.

Additionally, a plurality of related thread groups can be active (in different phases of execution) at the same time within one or more SMs 310. This collection of thread groups is referred to herein as a “cooperative thread array” (“CTA”) or “thread array.” The size of a particular CTA is equal to q*k, where k is the number of concurrently executing threads in a thread group, which is typically an integer multiple of the number of execution units within the SM 310, and q is the number of thread groups simultaneously active within the one or more SMs 310. In various embodiments, a software application written in the compute unified device architecture (CUDA) programming language describes the behavior and/or operation of threads executing on GPC 208, including any of the behaviors and/or operations described herein. A given processing task can be specified in a CUDA program such that the SM 310 can be configured to perform and/or manage general-purpose compute operations.

In some embodiments, each SM 310 is coupled to a level one (L1) cache memory, or L1 cache 335 that supports, among other things, load (e.g., read access) and/or store (e.g., write access) operations performed by the execution units. Each SM 310 in a particular GPC 208 also has access to a level two (L2) cache, or L2 cache 340 that is shared among all SMs 310 in the particular GPC 208, and the L3 cache 213 that is shared among the GPCs 208 in PPU 202. In some embodiments, the L2 caches 340 and L3 cache 213 can be used to transfer data between threads. Persons skilled in the art will understand that the three levels of caches 335, 340, 213 illustrated in FIGS. 2 and 3 are provided as non-limiting examples of cache memory, and that in other examples, a PPU 202 can include and/or be coupled to fewer or more than three levels of cache. In some examples, the PPU 202 includes and/or is coupled to two levels of cache memory. In other examples, the PPU 202 includes and/or is coupled to four levels of cache memory, five levels of cache memory, or some other number of levels of cache memory.

In addition to various levels of cache memory, SMs 310 also have access to off-chip “global” memory, which can include PP memory 204 and/or system memory 104. It is to be understood that any memory external to PPU 202 can be used as global memory. As shown in FIGS. 2 and 3, the L3 cache 213 and/or the L2 caches 340 can be configured to receive and/or hold data requested from memory via memory interface 214 by an SM 310. Such data can include, without limitation, instructions, uniform data, and/or constant data. As will be described in more detail herein, each GPC 208 can have an associated memory management unit (MMU) that is configured to map virtual addresses into physical addresses. In various embodiments, MMU can reside either within GPC 208 or within the memory interface 214. The MMU includes a set of page table entries (PTEs) used to map a virtual address to a physical address of a tile or memory page and/or optionally a cache line index. The MMU can include address translation lookaside buffers (TLB) or caches that can reside within SMs 310, within one or more L1 caches 335, one or more L2 caches 340, the L3 cache 213, and/or within GPC 208.

In graphics and/or compute applications, GPC 208 can be configured such that each SM 310 is coupled to a texture unit 315 for performing texture mapping operations, such as determining texture sample positions, reading texture data, and/or filtering texture data. In operation, each SM 310 transmits a processed task to work distribution crossbar 330 in order to provide the processed task to another GPC 208 for further processing, or to store the processed task in an L2 cache 340 or an L3 cache 213, parallel processing memory 204, or system memory 104 via crossbar unit 210. In addition, a pre-raster operations (preROP) unit 325 is configured to receive data from an SM 310, direct data to one or more raster operations (ROP) units within partition units 215, perform optimizations for color blending, organize pixel color data, and/or perform address translations.

### Cache Memory Control

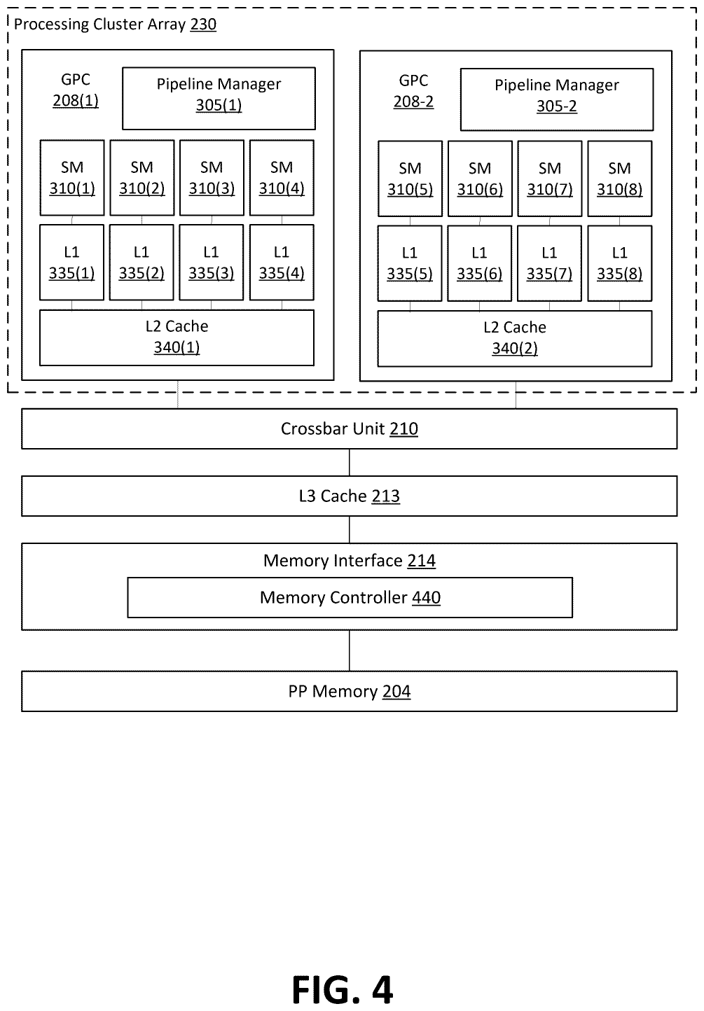

FIG. 4 is a more detailed illustration of an exemplar processing cluster array 230 included in the parallel processing unit 202 of FIG. 2, according to various illustrated embodiments. Persons skilled in the art will understand that the number of components included in the processing cluster array 230 illustrated in FIG. 4 are provided as a non-limiting example. Moreover, persons skilled in the art will understand that the exemplar processing cluster array illustrated in FIG. 4 can include more or fewer than the number of components illustrated in FIG. 4. As shown in FIG. 4, the exemplar processing cluster array 230 includes a first GPC 208(1) and a second GPC 208(2). The second GPC 208(1) is coupled to the first GPC 208(1) via the crossbar unit 210. Persons skilled in the art will understand that, in other examples, the processing cluster array 230 can include fewer or more than two GPCs 208. For example, a processing cluster array 230 can include three GPCs 208, four GPCs 208, or more.

The first GPC 208(1) includes a respective pipeline manager 305(1) and a plurality of SMs 310(1)-310(4). In the illustrated example of FIG. 4, the first GPC 208(1) includes four SMs 310(1)-310(4). However, persons skilled in the art will understand that in other examples, the first GPC 208(1) can include fewer or more than four SMs 310. Each SM 310 included in the GPC 208(1) is coupled to a respective L1 cache 335 included in the first GPC 208(1). For example, the SM 310(1) is coupled to the L1 cache 335(1), the SM 310(2) is coupled to the L1 cache 335(2), the SM 310(3) is coupled to the L1 cache 335(3), and the SM 310(4) is coupled to the L1 cache 335(4). The L2 cache 340(1) included in the first GPC 208(1) is coupled to every L1 cache 335 included in the first GPC 208(1) and to the L3 cache 213 by the crossbar unit 210.

Similarly, the second GPC 208(2) includes a respective pipeline manager 305(2) and a plurality of SMs 310(5)-310(8). In the illustrated example of FIG. 4, the second GPC 208(2) includes four SMs 310(5)-310(8). However, persons skilled in the art will understand that in other examples, the second GPC 208(2) can include fewer or more than four SMs. Each SM 310 included in the second GPC 208(2) is coupled to a respective L1 cache 335 included in the second GPC 208(2). For example, the SM 310(5) is coupled to the L1 cache 335(5), the SM 310(6) is coupled to the L1 cache 335(6), the SM 310(7) is coupled to the L1 cache 335(7), and the SM 310(8) is coupled to the L1 cache 335(8). The L2 cache 340(2) included in the second GPC 208(2) is coupled to every L1 cache 335 included in the second GPC 208(2) and to the L3 cache 213 by the crossbar unit 210.

As described above with respect to FIGS. 2 and 3, each SM 310 included in the processing cluster array 230 is configured to process one or more thread groups. As used herein, a “thread group” or “warp” refers to a group of threads concurrently executing the same program on different input data, with one thread of the group being assigned to a different execution unit within an SM 310. A thread group can include fewer threads than the number of execution units within the SM 310, in which case some of the execution can be idle during cycles when that thread group is being processed. A thread group can also include more threads than the number of execution units within the SM 310, in which case processing can occur over consecutive clock cycles. Since each SM 310 can support up to G thread groups concurrently, it follows that up to G*Q thread groups can be executing in GPC 208 at any given time.

Additionally, a plurality of related thread groups can be active (in different phases of execution) at the same time within one or more SMs 310. This collection of thread groups is referred to herein as a “cooperative thread array” (“CTA”) or “thread array.” The size of a particular CTA is equal to q*k, where k is the number of concurrently executing threads in a thread group, which is typically an integer multiple of the number of execution units within an SM 310, and q is the number of thread groups simultaneously active within the one or more SMs 310. In various embodiments, a software application written in the compute unified device architecture (CUDA) programming language describes the behavior and/or operation of threads executing on GPC 208, including any of the behaviors and/or operations described herein. A given processing task can be specified in a CUDA program such that an SM 310 can be configured to perform and/or manage general-purpose compute operations.

In many instances, threads in a CTA can be executing across multiple different SMs 310 at the same time. In some examples, SMs 310 in the same GPC 208 concurrently execute threads in the same CTA. For example, SM 310(1) and 310(2) included in the first GPC 208(1) can concurrently execute threads in the same CTA. In some examples, SMs 310 included in different GPCs 208 can concurrently execute threads in the same CTA. For example, SM 310(1) in the first GPC 208(1) and SM 310(5) in the second GPC 208(2) can concurrently execute threads in the same CTA. When a particular SM 310 executes threads in a CTA, the particular SM 310 accesses and/or modifies an object (e.g., data) stored in one or more cache memories, such as the L1 cache 335 coupled to the particular SM 310, an L2 cache 340, and/or the L3 cache 213. The techniques disclosed herein are implemented to maintain consistency between the data stored in different cache memories that is accessed and/or modified by SMs 310 executing threads in the same CTA.

With the disclosed techniques, a dynamic scope programming model can be applied to maintain consistency across CTA threads executing concurrently across multiple SMs 310. This dynamic scope programming model, or scoping mechanism, allows for a programmer to arbitrarily group threads that require a coherent view of any shared objects, such as memory locations that can be tracked to some minimum granularity (e.g., byte, sector, or cache line), into a scope group. In some embodiments, the programmer provides each defined scope group with a unique scope group identifier (ID) that identifies the defined scope group. For example, the programmer can annotate within code of an application the threads, which comprise tasks and/or instructions, in a CTA with the unique scope group ID to identify that the respective threads belong to the scope group associated with the unique scope group ID. As an example, a programmer can annotate a memory access request, such as a “load” command, with a scope group ID “SG0” to identify that the load command “load.SG0” is associated with the scope group SG0. Accordingly, if a thread associated with, or within, a scope group accesses and/or modifies an object, the access and/or modification to the object can be tracked in all cache memories between the SM 310 serving the thread and the last level cache that initially fetched a copy of that object from memory. In some embodiments, in addition to or in lieu of threads belonging to scope groups being annotated within the code of an application, threads belonging to scope groups can also be annotated by a driver and/or a scheduler.

When an object in cache and/or other memory is accessed and/or modified by an SM 310 executing threads in a scope group, the object itself can also be tagged with the scope group ID to distinguish the memory access of the object from memory accesses associated with other scope groups (e.g., from different kernels). In this regard, a particular cache memory can distinguish between the memory accesses originating from different groups of threads, or scope groups, that are not cooperating because the scope group IDs associated with the different memory accesses would not match. As will be described in more detail herein, a scope group ID is a globally unique ID associated with a scope group of cooperative threads that is a function of program, kernel, and dynamic scope identifiers within a coherent cache hierarchy.

In various embodiments, the memory controller 440 facilitates communication between a memory device (e.g., the one or more L1 caches 335, the one or more L2 caches 340, the L3 cache 213, etc.) and other components of processing system. For example, the memory controller can provide control signals to enable specific bit cells included in a bit array included in a memory device. In such instances, the memory controller 440 provides such signals to control access during a clock cycle to read data from the specific bit cells and/or write data into the specific bit cells. As will be discussed in further detail below, the memory controller 440 can cause one or more of the memory devices to operate in a specific timing mode. For example, the memory controller 440 can cause a memory device to operate in a synchronous mode (e.g., a sync-only mode, a selected sync mode from multiple modes, etc.). In such instances, a common clock signal asserts and/or de-asserts various components in the memory devices.

Additionally or alternatively, in some embodiments, the memory controller 440 operates in a hybrid mode. While in the hybrid mode, the memory controller 440 generates an additional clock signal (e.g., the self-timing clock signal). In such instances, the memory controller 440 can control the timing of the self-timing clock signal. For example, when operating in a self-timing mode, the self-timing clock signal precedes the second rising edge of the clock signal, where the self-timing clock signal asserts and/or de-asserts various components in the memory devices. When operating in the sync mode within the hybrid mode, the self-timing clock signal succeeds the second rising edge of the clock signal, where the clock signal asserts and/or de-asserts each of components in the memory devices in lieu of the self-timing clock signal.

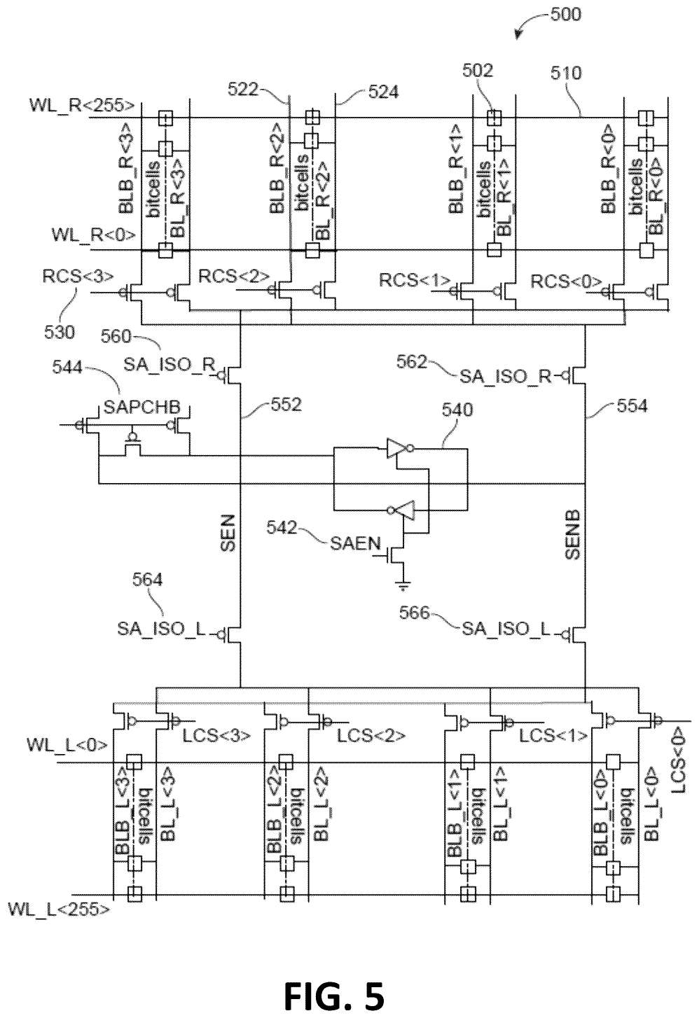

FIG. 5 is a block diagram of a memory array and access logic of a cache memory of FIG. 4, according to the various embodiments. As shown, the bit array 500 includes, without limitations, a plurality of bit cells 502, a plurality of word lines 510, a plurality of positive bit lines 522, a plurality of negative bit lines 524, a plurality of row column select circuits 530, a sense amplifier circuit 540, a sense amplifier precharge circuit 544, a positive differential signal 552, a negative differential signal 554, and isolation circuits 564-566.

As shown, the bit array 500 includes a plurality of memory cells (e.g., the bit cells 502) are connected to a plurality of bit lines (e.g., the positive bit line (BL) 522 and the negative bit line (BLB) 524) to form a bit line differential via the differential signals 552, 554. In various embodiments, the bit array 500 shown has multiple (e.g., N rows) and multiple columns (e.g., M columns). Each bit cell 502 is connected to a word lines (WL) 510, which are arranged in a direction perpendicular to the pairs of bit lines 522, 524.

In various embodiments, the memory controller 440 enables a single word line 510 (e.g., the word line 510 “WL_R<255>”). A row decoder (not shown) processes address information transmitted by the memory controller 404 and activates the corresponding by enabling word line 510 corresponding to the address. Similarly a column decoder (not shown) processes address information and activates the necessary columns by activating the specific pair of bit lines 522, 524. The number of columns activated depends on the size of the word. For example, when the memory array 500 supports a 32-bit word, the column decoder can activate 32 columns. In some embodiments, the column decoder provides active signals to specific read column select (RCS) circuits 530 to enable specific columns in the bit array. In some embodiments, a column multiplexor (not shown) can be used to multiplex the bit lines 522, 524 in the columns into the sense amplifier 540, thereby reducing the required number of sense amplifiers 540 needed for the bit array 500. Additionally or alternatively, the column decoder sends information the specific bit cells 502 in to bit array 500 via the bit lines 522, 524. In such instances, one or more write drivers cause the bit lines 522, 524 to write data into a selected bit cell 502 during a write operation.

In various embodiments, the sense amplifier 540 is connected to the sense amplifier precharge (SAPCH) circuit 544 the precharge circuit 544 charges the pair of bit lines 522, 524 connected to the sense amplifier 650 to the supply voltage. The sense amplifier 540 receives an enable (SAEN) signal 542 that enables the sense amplifier 540 during a read operation. The sense amplifier 540 determines the differential signals 552, 554 corresponding to a selected pair of bit lines 522, 524 and output data corresponding to the differential value, which represents the value of the data stored in the selected bit cell 502. For example, the sense amplifier 540 can compare the differential determined from the differential signals 552, 554 and output a data value when the differential exceeds a predetermined threshold.

In some embodiments, the bit array 500 includes one or more precharge (PCH) circuits (not shown). When the bit array 500 is not active (e.g., no read or write operation), the precharge circuit is enabled, keeping the voltages on the bit line high. When a read operation or write operation occurs, the precharge circuit is disabled and a single word line signal 510 is enabled. When the word line signal 510 is enabled, a given bit cell 502 within a column is able to affect the voltage on the connected bit lines 522, 524 in the bit line differential. In various embodiments, the bit cell 502 includes a latch where one side stores a high logical value, and the other side stores a low logical value. When the access transistors of the bit cell 502 are enabled by the word line signal 510, the bit cell 502 affects the bit lines 522, 524 by discharging one of the bit lines, BL 522 or BLB 524, depending on which side of the latch stores the low logical value. The sense amplifier 540 detects a small differential signal 552, 554 provided by the bit lines 522, 524 and amplifies the differential in order to identify the data value stored in the selected bit cell 502. Once discharged, the bit line 522, 524 is re-charged by the pre-charge circuit.

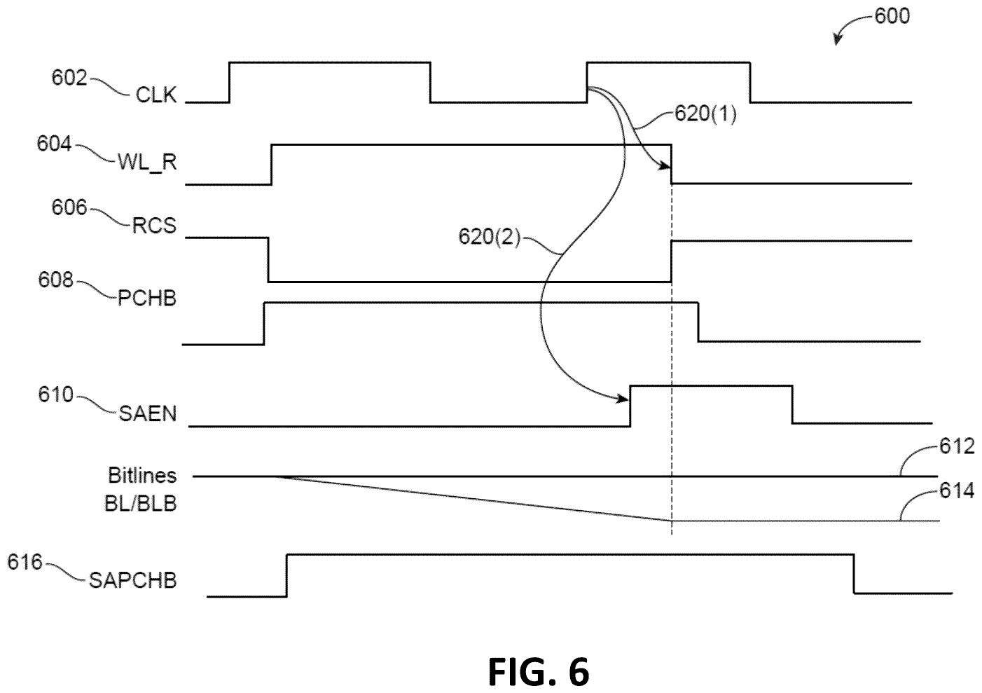

FIG. 6 illustrates exemplar waveforms associated with the memory array and access logic of FIG. 4 operating in a sync timing mode, according to the various embodiments. As shown, the waveforms 600 includes a clock signal 602, a word line signal 604, a read column select signal 606, a precharge signal 608, a sense amplifier enable signal 610, a positive bit line signal 612, a negative bit line signal 614, and a sense amplifier precharge signal 616.

In operation, the memory controller 440 causes the bit array 500 to operate in a pure sync mode. During the pure sync mode, the rising edge of the clock (CLK) signal 602 triggers one or more other control signals, enabling or disabling access to a bit cell during a clock cycle. For example, during a read operation, the first rising edge of the clock signal enables the word line (WL) signal 604 and the precharge (PCH) signal 608 for the precharge is disabled, causing the voltages on the bit lines 522, 524 to no longer be held high. When the word line signal is enabled, one of the bit lines 522, 524 discharges, creating a differential between the bit line (BL) signal 612 and the negative bit line (BLB) signal 614. The second rising edge of the clock signal 602 triggers 620 (e.g., 620(1), 620(2)) that asserts the sense amplifier enable (SAEN) signal 610 as well as de-asserts the word line signal 604. The sense enable signal 610 causes the sense amplifier 540 to detect the differential between the bit line signals 612, 614 and output a data value based on the differential.

In various embodiments, the word line signal 604 needs to be enabled during the entire clock period of the clock signal 602 in order to discharge either of the bit lines 522, 524 such that the bit line signals 612, 614 reach a threshold differential. In such instances, the sense amplifier 540 detects the differential between the bit line signals 612, 614 during the subsequent clock period. Similarly, during a write cycle, a write driver discharges either of the bit lines 522, 524 to write to a specific bit cell 502 during a subsequent clock period.

### Hybrid Timing Mode for Pipelined Cache Memories

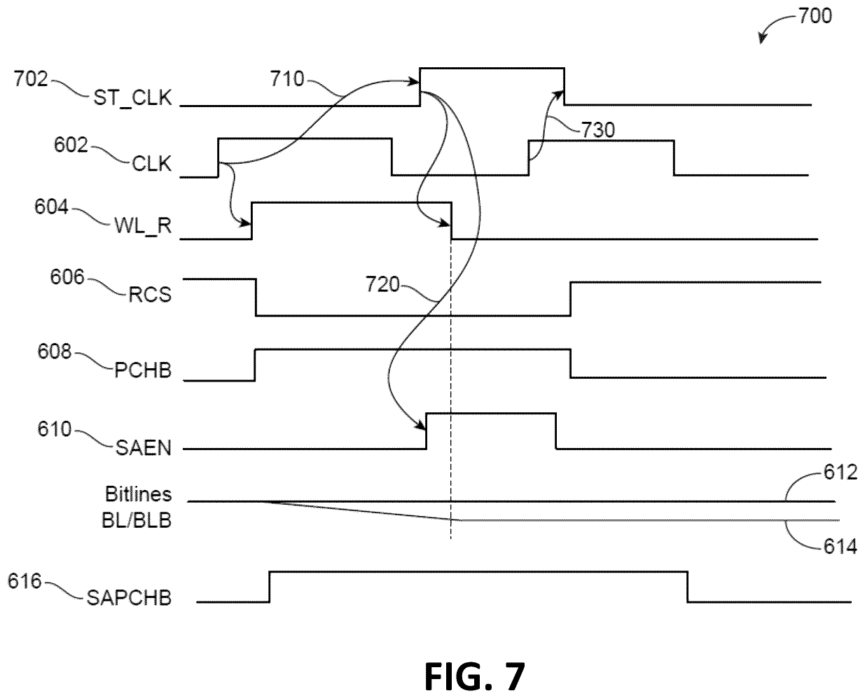

FIG. 7 illustrates exemplar waveforms associated with the memory array and access logic of FIG. 4 operating in a self-timing trigger mode, according to the various embodiments. As shown, the waveforms 700 includes a self-timing clock signal 702, the clock signal 602, the word line signal 604, the read column select signal 606, the precharge signal 608, the sense amplifier enable signal 610, the positive bit line signal 612, the negative bit line signal 614, and the sense amplifier precharge signal 616.

In operation, the memory controller 440 operating in the hybrid mode causes the bit array 500 to operate in a self-timing mode. While in the self-timing mode, the memory controller 440 generates the self-timing clock (ST_CLK) signal 702 that is asserted by the clock signal 602. During the initial phase of the self-timing mode, the rising edge of the clock (CLK) signal 602 triggers 710 one or more other control signals, including the self-timing clock signal 702 and the word line signal 604. The precharge (PCH) signal 608 is disabled, causing the voltages on the bit lines 522, 524 to be held high. When the word line signal is enabled, one of the bit lines 522, 524 discharges, creating a differential between the bit line (BL) signal 612 and the negative bit line (BLB) signal 614.

In various embodiments, due to the characteristics of the bit array (e.g., input voltage, capacitor characteristics, transistor characteristics, etc.), the differential between the bit line signals 612, 614 exceeds the predetermined threshold earlier in the clock cycle of the clock signal 602. In such instances, the first rising edge of the self-timing signal 702, precedes the second rising edge of the clock signal 602. The first rising edge of the self-timing signal 702 thus generates one or more triggers 720 that assert the sense amplifier enable (SAEN) signal 610 and de-assert the word line signal 604. While in the self-timing mode, the word line is de-asserted earlier in the clock cycle, thus consuming less power than during the sync mode. The sense enable signal 610 causes the sense amplifier 540 to detect the differential between the bit line signals 612, 614. The sense amplifier temporarily acts as a latch circuit and stores the data value before outputting the data value later in the clock cycle of the clock signal 602. In some embodiments, the second rising edge of the clock signal 602 de-asserts the self-timing clock signal 702.

Additionally or alternatively, in various embodiments, the write driver during a write cycle discharges either of the bit lines 522, 524 to generate the differential between the bit line signals 612, 614. The writer driver causes the bit lines 522, 524 to write to a specific bit cell 502 before the second rising edge of the clock signal 602. In such instances, the word line 604 is de-asserted earlier, thus reducing the amount of power that the bit array consumes. In some instances, during a write cycle, the word line 510 for a given address is continually enabled for the entire clock period to enable a write to each of the bit cells 502 included in the address. During the clock period, the bit cells 502 that are half-selected (e.g., the bit cells 502 that are connected to a bit line pair not chosen by the column decoder), discharge the bit lines, thereby wasting dynamic power by keeping the word line on for longer than is necessary to complete the write cycle. By self-timing the write operation, the WL pulse is reduced, thus reducing the power wastage due to half-selected bit cells.

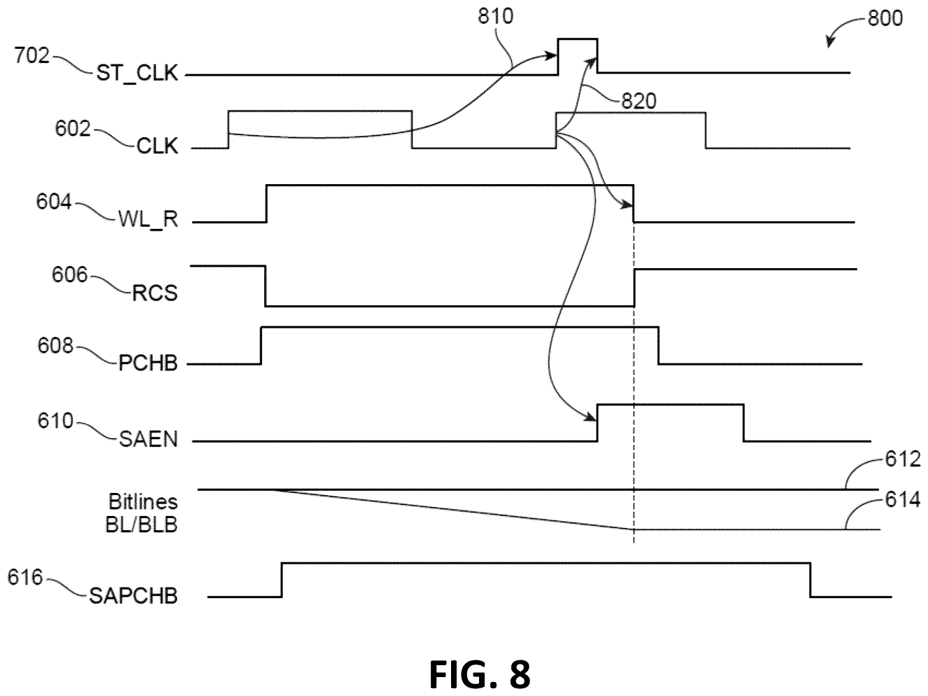

FIG. 8 illustrates exemplar waveforms associated with the memory array and access logic of FIG. 4 operating in a sync timing trigger mode, according the various embodiments. As shown, the waveforms 700 includes a self-timing clock signal 702, the clock signal 602, the word line signal 604, the read column select signal 606, the precharge signal 608, the sense amplifier enable signal 610, the positive bit line signal 612, the negative bit line signal 614, and the sense amplifier precharge signal 616.

In operation, the memory controller 440 operating in the hybrid mode causes the bit array 500 to operate in a sync trigger mode. While in the sync trigger mode, the memory controller 440 generates the self-timing clock (ST_CLK) signal 702 that is asserted by the clock signal 602. During the initial phase of the sync trigger mode, the first rising edge of the clock (CLK) signal 602 triggers 810 one or more other control signals, including the self-timing clock signal 702 and the word line signal 604. For example, the first rising edge of the clock signal enables the word line (WL) signal 604 and the precharge (PCH) signal 608 is disabled, causing the voltages on the bit lines 522, 524 to no longer be held high. When the word line signal is enabled, one of the bit lines 522, 524 discharges, creating a differential between the bit line (BL) signal 612 and the negative bit line (BLB) signal 614.

In various embodiments, due to the characteristics of the bit array (e.g., input voltage, capacitor characteristics, transistor characteristics, etc.), the differential between the bit line signals 612, 614 exceeds the predetermined threshold later in the clock cycle of the clock signal 602. In such instances, the first rising edge of the self-timing signal 702 succeeds the second rising edge of the clock signal 602. The second rising edge of the clock signal 602 thus generates triggers 820 that assert the sense amplifier enable (SAEN) signal 610 as de-asserts the word line signal 604. The sense enable signal 610 causes the sense amplifier 540 to detect the differential between the bit line signals 612, 614. Similarly, during a write cycle, the enabled word line signal 602 charges bit lines 522, 524 and the write driver causes the bit lines 522, 524 to write to a specific bit cell 502 during a subsequent clock period.

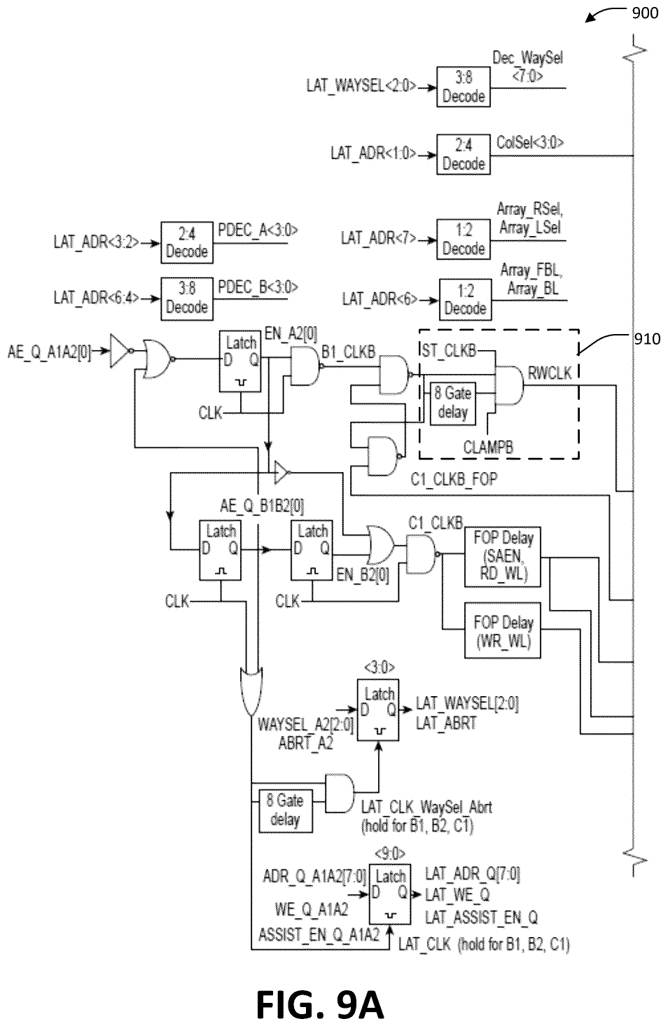

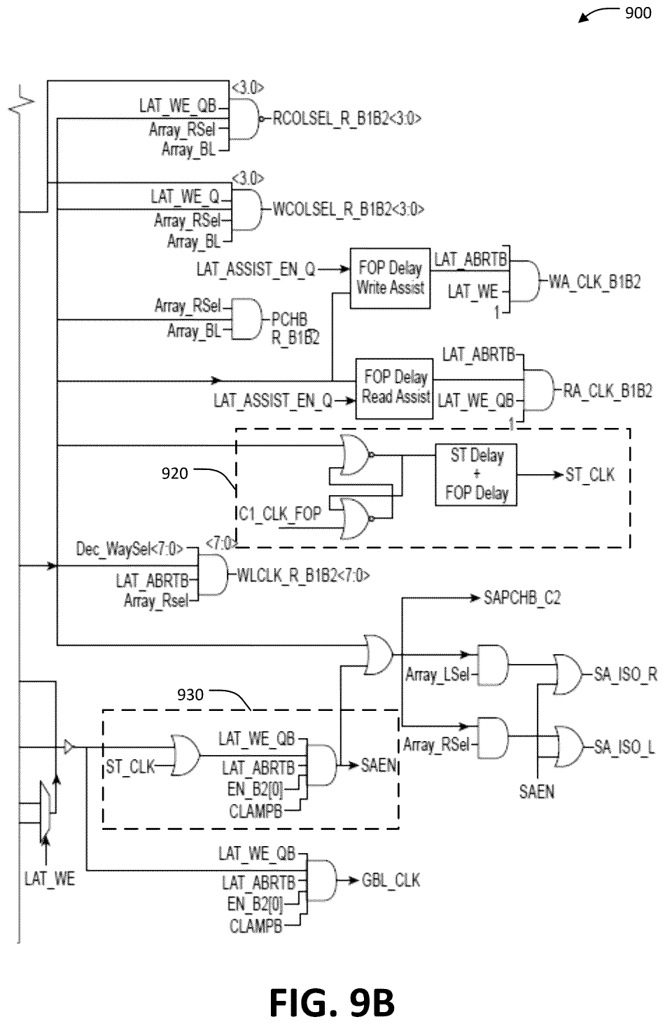

FIGS. 9A-9B is a diagram of sequential logic included in the memory controller of FIG. 4, according to the various embodiments. As shown, the logic circuit 900 includes, without limitation, clock selection logic 910, self-timing clock logic 920, and sense amplifier enable logic 930.

In various embodiments, the logic circuit 900 is included in the memory controller 440 and generates various timing signals and/or control signals to control various components of the bit array 500. For example, the clock selection logic 910 generates a read/write clock (RWCLK) signal (e.g., the WL_R 604) that is used to enable components of the bit array during the read cycle and/or the write cycle.

The self-timing clock logic 920 includes a flip-flop circuit and a delay circuit. In various embodiments, the self-timing clock logic 920 receives the read/write clock signal from the clock selection logic 910. The flip-flop circuit and the delay circuit operate in conjunction to respond to the read/write clock signal by generating the self-timing clock signal 702. In this manner, the self-timing clock signal can be adjusted to precede or succeed the clock signal triggering the self-timing clock logic 920 based on configuring the delay circuit.

The sense amplifier enable logic 930 receives the read/write clock signal from the clock selection logic 910 and the self-timing clock signal from the self-timing clock logic 920. In various embodiments, the sense amplifier enable logic 930 includes sequential logic to select the earlier of the read/write clock signal or the self-timing clock signal. In this manner, the memory controller 440 operating in the hybrid mode can switch between the self-timing mode (where the self-timing clock signal 702 triggers the sense amplifier enable signal 610) and the sync trigger mode where the clock signal 602 triggers the sense amplifier enable signal 610).

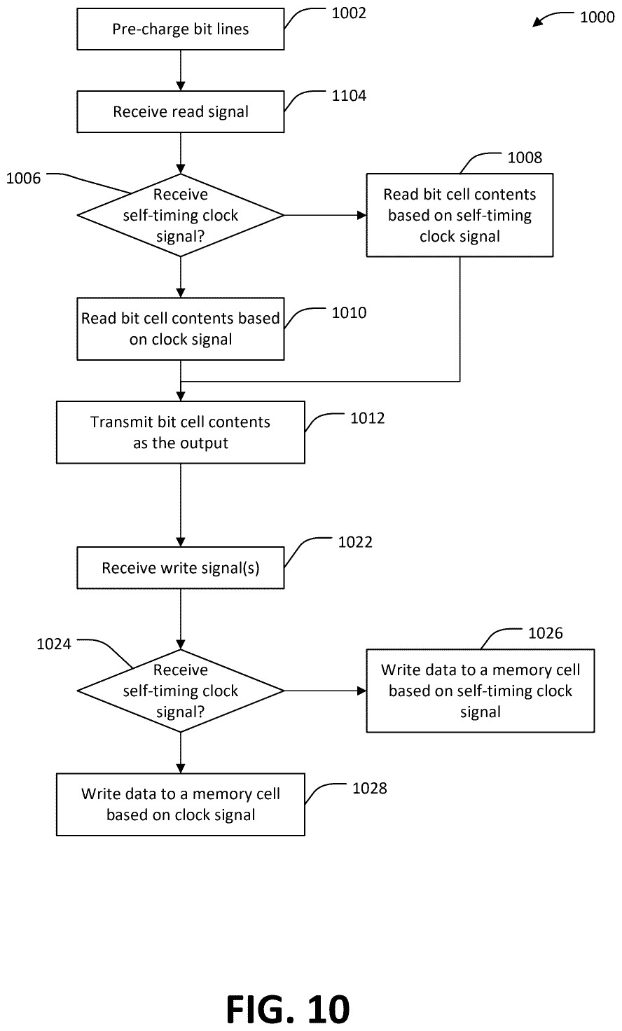

FIG. 10 sets forth a flowchart of method steps for reading data from and writing data to a cache memory, according to the various embodiments. Although the method steps are described in conjunction with the system of FIGS. 1-9B, persons skilled in the art will understand that any system configured to perform the method steps, in any order, is within the scope of the various embodiments.

As shown, a method 1000 begins at step 1002, where the bit array 500 pre-charges the bit lines of the bit array 500. In various embodiments, when the bit array 500 is not active (e.g., no read or write operation is occurring), the precharge circuit is enabled, keeping the voltages on a given bit line 522, 524 high. At step 1004, the bit array 500 receives a read signal. In various embodiments, the memory controller 440 generates a clock signal 602 that operates as a read/write signal, where a rising edge of the clock signal 602 triggers a read operation. In some embodiments, the memory controller also transmits an address to acquire data stored in an address of the bit array 500. The read signal enables the word line signal 604. When the word line signal 604 is enabled, one of the bit lines 522, 524 discharges, creating a differential between the bit line signal 612 and the negative bit line signal 614.

At step 1006, the bit array 500 potentially receives self-timing clock signal 702 before receiving the clock signal 602. In various embodiments, the memory controller 440 operates in a hybrid mode and generates, in addition to the clock signal 602, a self-timing clock signal 702. When the memory controller 440 operates in a self-timing mode, the bit array 500 receives a rising edge of the self-timing clock signal 702 before receiving a subsequent rising edge of the clock signal 602. When the bit array 500 receives the rising edge of the self-timing clock signal 702 first, the bit array 500 proceeds to step 1008. Otherwise, the bit array 550 receives the subsequent rising edge of the clock signal 602 and proceeds to step 1010.

At step 1008, the bit array 500 reads the bit cell contents based on the self-timing clock signal 702. In various embodiments, the self-timing clock signal 702 triggers the sense amplifier enable signal 610 to enable the sense amplifier 540 to determine the differential of the bit lines 522, 524 that were charging during in response to the read signal. The self-timing signal 702 thus generates triggers 720 that also de-asserts the word line signal 604. While in the self-timing mode, the word line is de-asserted earlier in the clock cycle, thus consuming less power than during the sync mode. The sense enable signal 610 causes the sense amplifier 540 to detect the differential between the bit line signals 612, 614. The sense amplifier temporarily acts as a latch circuit and stores the data value.

At step 1010, the bit array 500 reads the bit cell contents based on the clock signal 602. In various embodiments, the clock signal 602 precedes the self-timing clock signal 702 and thus generates one or more triggers 820 that assert the sense amplifier enable signal 610 as de-assert the word line signal 604. The sense enable signal 610 causes the sense amplifier 540 to detect the differential between the bit line signals 612, 614.

At step 1012, the bit array 500 transmits the bit cell contents as the output. In various embodiments, the sense amplifier 540 outputs a data value based on the differential detected between the bit lines 522, 524. For example, the sense amplifier precharge circuit 544 can initially precharge the sense amplifier 540 during the first cycle. During a subsequent clock cycle, the sense amplifier 540 discharges, generating an output signal that indicates the data value that was stored in the bit cell.

At step 1022, the bit array 500 receives a write signal. In various embodiments, the memory controller 440 generates a clock signal 602 that operates as a read/write signal, where a rising edge of the clock signal 602 triggers a write operation. In some embodiments, the memory controller also transmits an address to store data at bit cells corresponding to the address within the bit array 500. The write signal also enables the word line signal 604. When the word line signal 604 is enabled, one of the bit lines 522, 524 charges, creating a differential between the bit line signal 612 and the negative bit line signal 614.

At step 1024, potentially receives self-timing clock signal 702 before receiving the clock signal 602. In various embodiments, the memory controller 440 operates in a hybrid mode and generates, in addition to the clock signal 602, a self-timing clock signal 702. When the memory controller 440 operates in a self-timing mode, the bit array 500 receives a rising edge of the self-timing clock signal 702 before receiving a subsequent rising edge of the clock signal 602. When the bit array 500 receives the rising edge of the self-timing clock signal 702 first, the bit array 500 proceeds to step 1026. Otherwise, the bit array 550 receives the subsequent rising edge of the clock signal 602 and proceeds to step 1028.

At step 1026, the bit array 500 writes the data into the bit cell based on the self-timing clock signal 702. In various embodiments, the self-timing clock signal 702 de-asserts the word line signal 604. The write driver during a write cycle discharges bit lines 522, 524 to generate the differential between the bit signals 612, 614. The writer driver causes the bit lines 522, 524 to write to a specific bit cell 502 before the second rising edge of the clock signal 602.

At step 1028, the bit array 500 writes data to the bit cell contents based on the clock signal 602. In various embodiments, the clock signal 602 precedes the self-timing clock signal 702 and thus generates one or more triggers 820 that de-assert the word line signal 604. The write driver during a write cycle discharges bit lines 522, 524 to generate the differential between the bit signals 612, 614 and store data during the subsequent clock cycle.

In sum, a memory controller controls access to one or more bit cells in a bit array of a cache memory. During a clock cycle, the memory controller transmits a clock signal to the cache memory. The memory controller also transmits a self-timing clock signal to the cache memory. The first rising edge of the clock signal enables a word line for an address within the cache memory. While the word line is enabled, each bit cell in the word line is accessible. When the memory controller is operating in a self-timing mode, the rising edge of the self-timing clock signal precedes the second rising edge of the clock signal. When the memory controller is operating in a sync mode, the rising edge of the self-timing clock signal occurs after the second rising edge of the clock signal. The next rising edge of either the clock signal or the self-timing disables the world line, causing each bit cell in the word line to become inaccessible.

During a read cycle, a pair of bit lines for a given bit cell discharge based on the contents of the bit cell. A sense amplifier compares the differential between the pair of bit lines and a threshold, reading from the bit cell when the differential exceeds the threshold. When operating in self-timing trigger mode, the rising edge of a self-timing clock signal disables the word line and enables the sense amplifier. Otherwise, when operating in sync timing trigger mode, the second rising edge of the clock signal disables the word line and enables the sense amplifier. When sense amplifier is enabled, the sense amplifier compares the differential between the bit lines to a predetermined threshold. Based on the comparison, the differential is transmitted to an output. During a write cycle, pair of bit lines for a given bit cell discharge based on data that is to be written to the bit cell. The data is written to the bit cell before the word line is disabled. When operating in self-timing trigger mode, disables the word line. Otherwise, when operating in sync timing trigger mode, the second rising edge of the clock signal disables the word line.

At least one technical advantage of the disclosed technique relative to the prior art is that the disclosed techniques reduce the amount of power consumed when data is read from or written to cache memory. More specifically, with the disclosed techniques, a memory controller includes logic to provide both a clock signal and a self-timing clock signal to a cache memory. When the cache memory is operable to operate in a self-time mode, the rising edge of the self-timing clock signal precedes the second rising edge of the clock signal, which allows the word line to be disabled earlier and the sense amplifier earlier to be enabled, thereby reducing the overall amount of dynamic power consumed by the cache memory due to the word line being enabled. Further, by triggering the word line to be disabled without modifying the clock signal, the memory controller can reduce the power consumption of the cache memory without modifying the timing of data transmission into or out of the cache memory. The cache memory can thus be included in various instruction pipelines without negatively impacting the operations of other components within the instruction pipeline running on that same clock signal. These technical advantages provide one or more technological improvements over prior art approaches.

1. In various embodiments, a computer-implemented method for controlling cache memory accesses comprises transmitting a first clock signal to the cache memory, wherein a first rising edge of the first clock signal asserts a word line, and transmitting a second clock signal to the cache memory, wherein a first rising edge of the second clock signal precedes a second rising edge of the first clock signal, and the first rising edge of the second clock signal de-asserts the word line.

2. The computer-implemented method of clause 1, wherein the first clock signal is transmitted by a first clock that comprises a conventional clock, and the second clock signal is transmitted by a second clock that comprises a self-timing clock.

3. The computer-implemented method of clause 1 or 2, where the first rising edge of the second clock signal precedes the second rising edge of the first clock signal during a self-timing trigger mode, and the second rising edge of the first clock signal precedes the first rising edge of the second clock signal during a sync trigger mode.

4. The computer-implemented method of any of claims 1-2, where the cache memory comprises an L3 cache.

5. The computer-implemented method of any of claims 1-4, where the cache memory comprises an L2 cache.

6. The computer-implemented method of any of claims 1-5, where a memory controller includes logic to generate the second clock signal from the first clock signal.

7. The computer-implemented method of any of claims 1-6, where the logic includes at least one of a flip-flop circuit or a delay circuit.

8. The computer-implemented method of any of claims 1-7, where the cache memory is included within an instruction pipeline.

9. The computer-implemented method of any of claims 1-8, where the cache memory comprises at least four bit columns.

10. The computer-implemented method of any of claims 1-9, further comprising transmitting a column select signal to the cache memory, wherein the column select signal asserts a subset of bit columns included in the at least four bit columns.

11. The computer-implemented method of any of claims 1-10, where the first rising edge of the second clock signal enables a sense amplifier to sense a pair of bit lines connected to a bit cell enabled by the word line.

12. The computer-implemented method of any of claims 1-11, where the sense amplifier latches a data value, determined from sensing the pair of bit lines, until the second rising edge of the first clock signal occurs, and further comprising determining a data value based on the pair of bit lines while the data value is latched.

13. The computer-implemented method of any of claims 1-12, further comprising driving a data signal to at least one bit cell enabled by the word line.

14. In various embodiment, one or more non-tangible computer readable media include instructions that, when executed, cause a memory controller to control cache memory accesses by performing the steps of transmitting a first clock signal to the cache memory, wherein a first rising edge of the first clock signal asserts a word line, and transmitting a second clock signal to the cache memory, wherein a first rising edge of the second clock signal precedes a second rising edge of the first clock signal, and the first rising edge of the second clock signal de-asserts the word line.

15. The one or more non-tangible computer readable media of clause 14, where the first clock signal is transmitted by a first clock that comprises a conventional clock, and the second clock signal is transmitted by a second clock that comprises a self-timing clock.

16. The one or more non-tangible computer readable media of clause 14 or 15, where the first rising edge of the second clock signal precedes the second rising edge of the first clock signal during a self-timing trigger mode, and the second rising edge of the first clock signal precedes the first rising edge of the second clock signal during a sync trigger mode.

17. The one or more non-tangible computer readable media of any of clauses 14-16, where the memory controller includes logic to generate the second clock signal from the first clock signal.

18. The one or more non-tangible computer readable media of any of clauses 14-17, where the first rising edge of the second clock signal enables a sense amplifier to sense a pair of bit lines connected to a bit cell enabled by the word line.

19. The one or more non-tangible computer readable media of any of clauses 14-18, where the sense amplifier latches a data value, determined from sensing the pair of bit lines, until the second rising edge of the first clock signal occurs, and further comprising determining a data value based on the pair of bit lines while the data value is latched.

20. In various embodiments, a system comprise a cache memory, and a memory controller coupled to the cache memory, where, in operation, the memory controller transmits a first clock signal to the cache memory, wherein a first rising edge of the first clock signal asserts a word line, and transmits a second clock signal to the cache memory, wherein a first rising edge of the second clock signal precedes a second rising edge of the first clock signal, and the first rising edge of the second clock signal de-asserts the word line.

Any and all combinations of any of the claim elements recited in any of the claims and/or any elements described in this application, in any fashion, fall within the contemplated scope of the present invention and protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

Aspects of the present embodiments may be embodied as a system, method or computer program product. Accordingly, aspects of the present disclosure may take the form of an entirely hardware embodiment, an entirely software embodiment (including firmware, resident software, micro-code, etc.) or an embodiment combining software and hardware aspects that may all generally be referred to herein as a “module,” a “system,” or a “computer.” In addition, any hardware and/or software technique, process, function, component, engine, module, or system described in the present disclosure may be implemented as a circuit or set of circuits. Furthermore, aspects of the present disclosure may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Aspects of the present disclosure are described above with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general-purpose computer, special purpose computer, or other programmable data processing apparatus to produce a machine. The instructions, when executed via the processor of the computer or other programmable data processing apparatus, enable the implementation of the functions/acts specified in the flowchart and/or block diagram block or blocks. Such processors may be, without limitation, general purpose processors, special-purpose processors, application-specific processors, or field-programmable gate arrays.

The flowchart and block diagrams in the figures illustrate the architecture, functionality, and operation of possible implementations of systems, methods and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

While the preceding is directed to embodiments of the present disclosure, other and further embodiments of the disclosure may be devised without departing from the basic scope thereof, and the scope thereof is determined by the claims that follow.

What is claimed is:

1. A computer-implemented method for controlling cache memory accesses, the method comprising:
transmitting a first clock signal to the cache memory, wherein a first rising edge of the first clock signal asserts a word line; and
transmitting a second clock signal to the cache memory, wherein a first rising edge of the second clock signal precedes a second rising edge of the first clock signal, and the first rising edge of the second clock signal de-asserts the word line.

2. The computer-implemented method of claim 1, wherein the first clock signal is transmitted by a first clock that comprises a conventional clock, and the second clock signal is transmitted by a second clock that comprises a self-timing clock.

3. The computer-implemented method of claim 2, wherein the first rising edge of the second clock signal precedes the second rising edge of the first clock signal during a self-timing trigger mode, and the second rising edge of the first clock signal precedes the first rising edge of the second clock signal during a sync trigger mode.

4. The computer-implemented method of claim 1, wherein the cache memory comprises an L3 cache.

5. The computer-implemented method of claim 1, wherein the cache memory comprises an L2 cache.

6. The computer-implemented method of claim 1, wherein a memory controller includes logic to generate the second clock signal from the first clock signal.

7. The computer-implemented method of claim 6, wherein the logic includes at least one of a flip-flop circuit or a delay circuit.

8. The computer-implemented method of claim 1, wherein the cache memory is included within an instruction pipeline.

9. The computer-implemented method of claim 1, wherein the cache memory comprises at least four bit columns.

10. The computer-implemented method of claim 9, further comprising transmitting a column select signal to the cache memory, wherein the column select signal asserts a subset of bit columns included in the at least four bit columns.

11. The computer-implemented method of claim 1, wherein the first rising edge of the second clock signal enables a sense amplifier to sense a pair of bit lines connected to a bit cell enabled by the word line.

12. The computer-implemented method of claim 11, wherein the sense amplifier latches a data value, determined from sensing the pair of bit lines, until the second rising edge of the first clock signal occurs, and further comprising determining a data value based on the pair of bit lines while the data value is latched.

13. The computer-implemented method of claim 1, further comprising driving a data signal to at least one bit cell enabled by the word line.

14. One or more non-tangible computer readable media including instructions that, when executed, cause a memory controller to control cache memory accesses by performing the steps of:
transmitting a first clock signal to the cache memory, wherein a first rising edge of the first clock signal asserts a word line; and
transmitting a second clock signal to the cache memory, wherein a first rising edge of the second clock signal precedes a second rising edge of the first clock signal, and the first rising edge of the second clock signal de-asserts the word line.

15. The one or more non-tangible computer readable media of claim 14, wherein the first clock signal is transmitted by a first clock that comprises a conventional clock, and the second clock signal is transmitted by a second clock that comprises a self-timing clock.

16. The one or more non-tangible computer readable media of claim 15, wherein the first rising edge of the second clock signal precedes the second rising edge of the first clock signal during a self-timing trigger mode, and the second rising edge of the first clock signal precedes the first rising edge of the second clock signal during a sync trigger mode.

17. The one or more non-tangible computer readable media of claim 14, wherein the memory controller includes logic to generate the second clock signal from the first clock signal.

18. The one or more non-tangible computer readable media of claim 14, wherein the first rising edge of the second clock signal enables a sense amplifier to sense a pair of bit lines connected to a bit cell enabled by the word line.

19. The one or more non-tangible computer readable media of claim 18, wherein the sense amplifier latches a data value, determined from sensing the pair of bit lines, until the second rising edge of the first clock signal occurs, and further comprising determining a data value based on the pair of bit lines while the data value is latched.

20. A system comprising:
a cache memory; and
a memory controller coupled to the cache memory, wherein, in operation, the memory controller:
transmits a first clock signal to the cache memory, wherein a first rising edge of the first clock signal asserts a word line; and
transmits a second clock signal to the cache memory, wherein a first rising edge of the second clock signal precedes a second rising edge of the first clock signal, and the first rising edge of the second clock signal de-asserts the word line.
